(19) United States
(12) Patent Application Publication
(10) Pub. No.: US 2012/0182657 A1
(43) Pub. Date: Jul. 19, 2012

(54) RATE OF CHANGE DIFFERENTIAL PROTECTION

(75) Inventors: Krishnaswamy Gururaj Narendra, Winnipeg (CA); David James Fedirchuk, Lle Des Chenes (CA); Nan Zhang, Winnipeg (CA)

(73) Assignee: ERLPhase Power Technologies Limited

(21) Appl. No.: 13/350,070

(22) Filed: Jan. 13, 2012

Related U.S. Application Data
(60) Provisional application No. 61/432,850, filed on Jan. 14, 2011.

(51) Int. Cl. H02H 3/08; G01R 31/00

(52) U.S. Cl. 361/87; 702/58; 702/59

(57) ABSTRACT

A method and algorithm are disclosed that can be used to determine if an electrical fault exists within a protection zone defined as in the area between specific current transformers. (CTs). Currents from CTs are brought into a microprocessor (or other device) that converts the analog currents into digital quantities. The current quantities are summed both vectorially and arithmetically by the microprocessor. The mathematical derivative of the vector and the arithmetic sums are compared in order to determine if an electrical fault exists within the protection zone. An electrical trip signal is generated by the microprocessor if the fault is deemed to be in the protection zone.

### CROSS-REFERENCE TO RELATED APPLICATIONS

This application claims the benefit of priority of U.S. Provisional Patent Application No. 61/432,850 filed Jan. 14, 2011, which is incorporated herein by reference in its entirety.

### FIELD

The present disclosure relates generally to the field of electrical power transmission and distribution systems, and in particular to methods, apparatus, and systems for fault detection and protection.

### BACKGROUND

The goal of a power system is to provide reliable power from sources of generation to customer loads. In the process of providing this power, the operation of the power system can be affected by abnormal conditions such as electrical faults. Good industry practice is to design the power system in such a manner where faulted components or protection zones can be isolated, if subjected to faults, in a way that minimizes the effect of these faults to the power system.

One proven method of providing fault protection is to measure the currents entering and leaving a protected zone. This method using the so called “Kirchoff's Law” technique, states that the currents leaving and entering a protection zone must be equal if no fault is present in this zone. This differential protection zone is defined by the measurement points which are typically current transformers (CTs) that provide smaller replica currents that can be measured by microprocessor devices.

Although relatively simple in theory, in actual practice, the currents obtained from the CTs can often be distorted due to measurement errors such as DC offsets or CT saturation. Load current present during the fault can also blind the protection from seeing faults with high impedances in the zone.

As a result, the microprocessor devices performing mathematical operations on the currents arrive at an erroneous result or decision because of the input currents. The distorted inputs result in distorted output. This can result in protection zones being tripped out unnecessarily (i.e. falsely ‘measuring’ a fault when there in fact is none) or not tripping when required (i.e. falsely ‘measuring’ no fault when in fact there is a fault) leading to a problem of risk to equipment and persons as well as creating additional outages on the power system.

US 2010/0202092 (Gajic et al.) discloses a “Differential Protection Method System and Device.”

The motivation for this innovation is to provide a method, algorithm, system, and devices that can enable the microprocessor device to make a correct decision as to fault location even when the input current quantities are distorted. Providing microprocessor decisions that are secure (don't produce a trip when not required) and reliable (provide trip when required) provide improved reliability and are import in the operation of a power system.

### SUMMARY

It is an object of the present disclosure to obviate or mitigate at least one disadvantage of previous systems, methods, and apparatus for power system protection and determining whether a fault resides inside our outside a protection zone.

A method and algorithm are disclosed that can be used to determine if an electrical fault exists within a protection zone defined as in the area between specific current transformers. (CTs). Currents from CTs are brought into a microprocessor (or other device) that converts the analog currents into digital quantities. The current quantities are summed both vectorially and arithmetically by the microprocessor. The mathematical derivative of the vector and the arithmetic sums are compared in order to determine if an electrical fault exists within the protection zone. An electrical trip signal is generated by the microprocessor if the fault is deemed to be in the protection zone. The algorithm may also use the current information present during the fault to not instigate a protection trip operation if the ensuing fault resides outside the protection zone and to trip if the fault is within the protection zone.

In a first aspect, the present disclosure provides a method of determining whether a fault resides inside or outside a protection zone, comprising the techniques described herein.

In a further aspect, the present disclosure provides a method for determining whether a fault is inside or outside a protection zone, including receiving phasor current quantities from a plurality of nodes, defining the protection zone between the plurality of nodes, determining an operating current (IO), determining a restraining current (IR), determining a time derivative of the operating current (d(IO)/dt), determining a time derivative of the restraining current (d(IR)/dt), comparing d(IO)/dt and d(IR)/dt, and generating a fault inside signal if d(IO)/dt>d(IR)/dt, the fault inside signal indicating that the fault is inside the protection zone. In an embodiment disclosed, voltages are utilized instead of, or in combination with, currents.

In an embodiment disclosed, the method includes generating the fault inside signal only if d(IO)/dt is positive and d(IR)/dt is positive.

In an embodiment disclosed, the method includes initiating a protection action in response to the fault inside signal. In an embodiment disclosed, the protection action comprises isolation of the protection zone.

In an embodiment disclosed, the method includes initiating a supervisory action in response to the fault inside signal. In an embodiment disclosed, the supervisory action comprises indicating the fault inside signal to an electrical device or a display or both. In an embodiment disclosed, the electrical device is a circuit breaker, relay, switch, thermal device, line monitor, device monitor, control system, or other protection or monitoring device. In an embodiment disclosed, the display is an operator panel or control system.

In an embodiment disclosed, the method is applied to each phase of a multiphase current.

In an embodiment disclosed, the current quantities include a distortion. In an embodiment disclosed, the distortion includes DC offsets, CT saturation, load current effects, or combinations thereof.

In an embodiment disclosed, the method includes repeating the method throughout at least a portion of a power network, comprising a plurality of protection zones, to locate the protection zone in which the fault is located. In an embodiment disclosed, the method is repeated iteratively to locate the protection zone in which the fault is located.

In a further aspect, the present disclosure provides a method for determining whether a fault is inside or outside of a protection zone, including receiving phasor current quantities from a first node and a second node, defining the protection zone between the first node and the second node, determining an operating current (IO), determining a restraining current (IR), determining a time derivative of the operating current (d(IO)/dt), determining a time derivative of the restraining current (d(IR)/dt), comparing d(IO)/dt and d(IR)/dt, and generating a fault inside signal if d(IO)/dt>d(IR)/dt, the fault inside signal indicating that the fault is inside the protection zone.

In a further aspect, the present disclosure provides a microprocessor based protection relay for a protection zone, between a first node and a second node, including current inputs adapted to receive current quantities from the first node and the second node, a microprocessor, having a timer, a calculator for determining an operating current (IO), a restraining current (IR), a rate of change of the operating current over time d(IO)/dt, and a rate of change of the restraining current over time d(IR)/dt, and a comparator for comparing d(IO)/dt and d(IR)/dt, and a fault indicator for generating a fault inside signal if d(IO)/dt>d(IR)/dt, the fault inside signal indicating that the fault is inside the protection zone, and a relay, responsive to the fault inside signal.

In an embodiment disclosed, the fault indicator further adapted to generate the fault inside signal only if d(IO)/dt is positive and d(IR)/dt is positive.

In an embodiment disclosed, the first node is a CT and the second node is a CT, and the microprocessor based protection relay is configured to isolate the protection zone by tripping the relay in response to the fault inside signal.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is a depiction of a generic percentage differential relay slope characteristic;

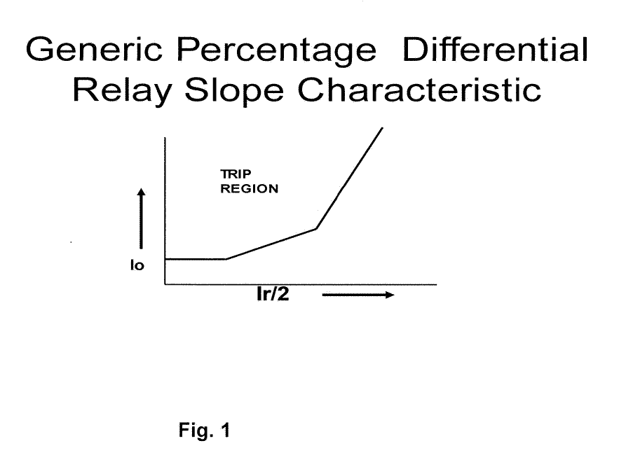

FIG. 2 is a depiction of an embodiment of the disclosed ROCOD logic; and

FIG. 3 is a simplified of a schematic of an embodiment of the present disclosure.

### DETAILED DESCRIPTION

The Rate of Change of Differential (ROCOD) technique essentially utilizes the first derivative or rate of change of the positive sequence operating current IO, and the restraining current IR, entering and leaving the protection zone.

A Review of Existing Concepts

The mathematical principle used in most low impedance differential protections used today to discriminate whether the fault is internal or external is done by using OPERATING current (IO) and RESTRAINING current (IR).

The operating current is the phasor sum of the currents entering and leaving the protection zone. The operating current applied for a ‘n’ input protection device becomes:

IO=|Î2+Î2+Î3+ . . . +În| (Eq. 1)

The restraining current is defined as: The sum of the absolute current magnitudes entering and leaving the protection zone.

IR=|Î1|+|Î2|+|Î3|+ . . . +|În|/W; (Eq. 2)

Typically, W has a value of 2.

The values and definitions of the operating and the restraining quantities are those generally used today for low impedance percentage differential relaying and has been in effect for at least the last 50 years of protective relay application starting with electromechanical relays.

In order to get a trip from the differential relay:

TRIP:=IO>f(IR) (Eq. 3),

Where ‘f’ implies some function of IR, which is the “slope characteristics”.

Rate of Change of Differential (ROCOD)

The disclosed method includes differentiating equation 3 (which is equivalent to differentiating equations 1 and 2) with respect to time on both the sides yields the ROCOD algorithm.

The ROCOD Algorithm

ROCOD is defined as:

TRIP:=d(IO)/dt>d(f(IR))/dt (Eq. 4)

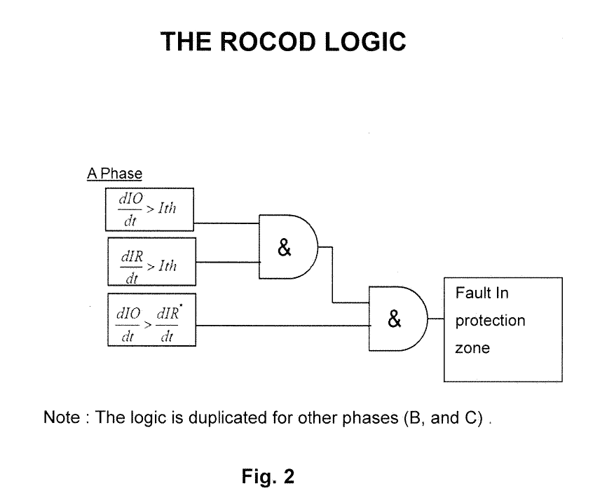

The above ROCOD Algorithm (Eq. 4) may be used to provide fault discrimination (internal or external to the protection zone) information, for example, as depicted in the functional logic diagram (FIG. 2).

The derivative principle used in the ROCOD technique eliminates the non fault load current effects on the restraining and operating currents of the protection zone. This is because the derivative of the constant non fault load current as seen in Eq. 4 will become zero.

For all internal fault conditions, if d(IO)/dt exceeds d(IR)/dt, the fault will reside within the protection zone. Hence Eq. 4 reflects the conditions for identifying internal faults reliably even under heavy load conditions or internal zone faults with high impedances.

Referring to FIG. 2 an embodiment of the ROCOD logic is shown.

1. In an embodiment disclosed, the ROCOD logic is performed on a phase by phase basis;

2. The first part of the logic is used to ensure that d(IO)/dt and d(IR)/dt are positive;

3. Next, the logic is used to check to see if d(IO)/dt is >d(IR)/dt, as will be the case of a fault in the protected zone.

4. If conditions 2 and 3 are true, the fault is determined to be within the protection zone.

If the fault is determined to be within the protection zone, then a protective action may be taken, for example tripping a relay or other protective device.

In an embodiment of disclosed, the ROCOD technique may be incorporated with a protection relay, such that upon determination that the fault is within the protection zone, a protection action is taken, such as isolation of the fault from the power system.

The protection action may include keeping the circuit active, or monitoring the fault level or fault duration or both, or tripping the relay to open the circuit if the fault level or fault duration exceeds some threshold fault level or fault duration or both, or the protection action may include another protection action, known to one skilled in the art. In an embodiment disclosed, the protection action may include isolating the protection zone from the rest of the power system.

The techniques described herein may be used for differential fault detection and protection of devices including, but not limited to, transformer, generator, transmission line, bus, switchgear, and other power devices. The techniques described herein may be used for circuit breaker, protection relay, switch, thermal device, line monitor, device monitor, or other protection or monitoring devices.

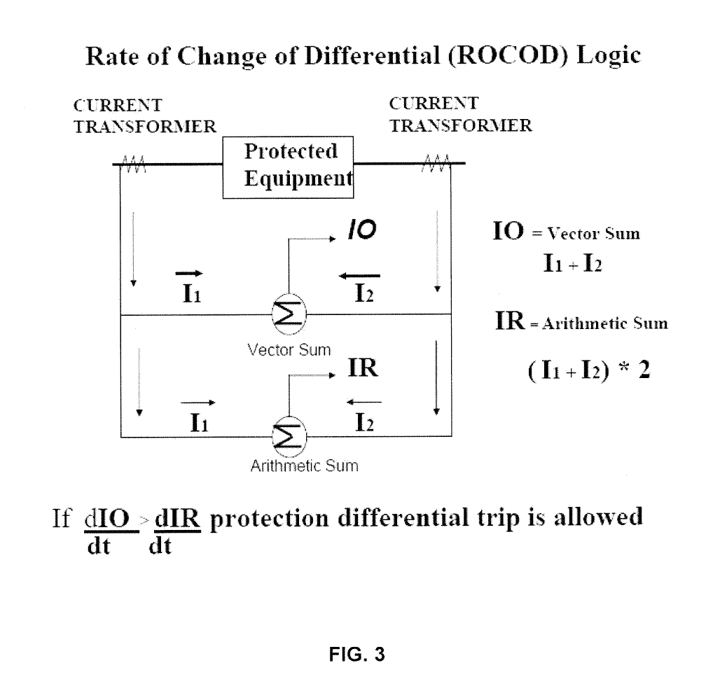

Referring to FIG. 3, an embodiment of the present disclosure is depicted applied to a power system. CT's, shown with protected equipment. Currents from the CT's are summed, both as a vector sum and as an arithmetic sum. If the time derivative (rate of change over time) of the operating current IO is greater than the time derivative (rate of change over time) of the restraining current, then differential trip is allowed.

In an embodiment disclosed, the described rate of change differential (ROCOD) may be used to confirm that indeed there is an actual fault within the protection zone. That is, if dIO/dt>dIR/dt, protection differential trip is allowed because the fault is an actual fault, not a false positive.

In the preceding description, the method and apparatus have been described in relation to current phasors. One skilled in the art recognizes that voltage phasors may be used instead of, or in combination with, current phasors.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

What is claimed is:

1. A method for determining whether a fault is inside or outside a protection zone, comprising:
receiving phasor current quantities from a plurality of nodes, defining the protection zone between the plurality of nodes;
determining an operating current (IO);
determining a restraining current (IR);
determining a time derivative of the operating current (d(IO)/dt);
determining a time derivative of the restraining current (d(IR)/dt);
comparing d(IO)/dt and d(IR)/dt, and generating a fault inside signal if d(IO)/d>d(IR)/dt, the fault inside signal indicating that the fault is inside the protection zone.

2. The method of claim 1, further comprising generating a fault inside signal only if d(IO)/dt is positive and d(IR)/dt is positive.

3. The method of claim 1, further comprising initiating a protection action in response to the fault inside signal.

4. The method of claim 3, wherein the protection action comprises isolation of the protection zone.

5. The method of claim 1, further comprising initiating a supervisory action in response to the fault inside signal.

6. The method of claim 5, wherein the supervisory action comprises indicating the fault inside signal to an electrical device or a display or both.

7. The method of claim 1 wherein the method is applied to each phase of a multiphase current.

8. The method of claim 1, wherein the current quantities include a distortion.

9. The method of claim 8, wherein the distortion includes DC offsets, CT saturation, load current effects, or combinations thereof.

10. The method of claim 1, further comprising repeating the method throughout at least a portion of a power network, comprising a plurality of protection zones, to locate the protection zone in which the fault is located.

11. A method for determining whether a fault is inside or outside of a protection zone, comprising:
receiving phasor current quantities from a first node and a second node, defining the protection zone between the first node and the second node;
determining an operating current (IO);
determining a restraining current (IR);
determining a time derivative of the operating current (d(IO)/dt);
determining a time derivative of the restraining current (d(IR)/dt);
comparing d(IO)/dt and d(IR)/dt, and generating a fault inside signal if d(IO)/dt>d(IR)/dt, the fault inside signal indicating that the fault is inside the protection zone.

12. A microprocessor based protection relay for a protection zone, between a first node and a second node, comprising:
current inputs adapted to receive current quantities from the first node and the second node;
a microprocessor, comprising:
a timer;
a calculator for determining an operating current (IO), a restraining current (IR), a rate of change of the operating current over time d(IO)/dt, and a rate of change of the restraining current over time d(IR)/dt; and
a comparator for comparing d(IO)/dt and d(IR)/dt;
a fault indicator for generating a fault inside signal if d(IO)/dt>d(IR)/dt, the fault inside signal indicating that the fault is inside the protection zone; and
a relay, responsive to the fault inside signal.

13. The microprocessor based protection relay of claim 12, the fault indicator further adapted to generate the fault inside signal only if d(IO)/dt is positive and d(IR)/dt is positive.

14. The microprocessor based protection relay of claim 12, wherein the first node is a CT and the second node is a CT, and the microprocessor based protection relay is configured to isolate the protection zone by tripping the relay in response to the fault inside signal.
